(19) United States
(12) Patent Application Publication
(10) Pub. No.: US 2018/0068635 A1
(43) Pub. Date: Mar. 8, 2018

(54) Shift Register Element, Method For Driving The Same, And Display Panel

(71) Applicant: SHANGHAI TIANMA AM-OLED CO., LTD., Shanghai (CN)

(72) Inventor: Renyuan ZHU, Shanghai (CN)

(21) Appl. No.: 15/797,339

(22) Filed: Oct. 30, 2017

(30) Foreign Application Priority Data
Jun. 27, 2017 (CN) 201710502225.0

(51) Int. Cl. G09G 5/00; G11C 19/28

(52) U.S. Cl. CPC G09G 5/006; G09G 2310/08; G09G 2310/0286; G11C 19/28

(57) ABSTRACT

The invention discloses a shift register element, a method for driving the same, and a display panel, where the shift register element includes an input module, a first control module, a second control module, a feedback and adjustment module, an output module, a first coupling module, and a second coupling module; the feedback and adjustment module feeds a signal from the output signal terminal back to a first node under the control of the second clock signal terminal, and the second control module connects the first node with a third node under the control of a first signal; and the first control module provides a second node with a signal of the first clock signal terminal or the first signal terminal under the control of a first clock signal terminal.

### CROSS-REFERENCES TO RELATED APPLICATIONS

This application claims priority to Chinese patent application No. CN201710502225.0 filed on Jun. 27, 2017, which is incorporated herein by reference in its entirety.

### FIELD

The present invention relates to the field of display technologies, and specifically to a shift register element, a method for driving the same, and a display panel.

### BACKGROUND

As display screens are developed continuously, there is an increasing demand for their stability from consumers. The stability of the display screens significantly relies on gate driver circuits, and shift register elements constitute major parts of the gate driver circuits.

At present, a shift register element is generally structured in 5T2C (that is, it includes five switch transistors and two capacitors). As illustrated in FIG. 1A which is a conventional schematic structural diagram of a shift register element, all of the first switch transistor M1 to the fifth switch transistor M5 are P-type thin film transistors. As illustrated in FIG. 1B which is a circuit timing diagram corresponding to the shift register element as illustrated in FIG. 1A. When a high-level signal is changed to a low-level signal at an output signal terminal OUT, both the fourth switch transistor M4 and the fifth switch transistor M5 are turned on, thus resulting in short-circuit current, so that there is higher power consumption on one hand, and the circuit may fail due to node potential contention on the other hand; and moreover the N2 node is floating while CK is at a high level, and when CKB is changed from a high level to a low level, then the N2 node may be coupled, so that the fifth switch transistor M5 may be turned on, thus resulting in an abnormal output, which may make the shift register element unstable.

### SUMMARY

Embodiments of the invention provide a shift register element, a method for driving the same, and a display panel so as to address the problem of an unstable output in the existing shift register element.

A shift register element according to an embodiment of the invention includes an input module, a first control module, a second control module, a feedback and adjustment module, an output module, a first coupling module, and a second coupling module, wherein:

the input module is connected with an input signal terminal and a first clock signal terminal, and configured to transmit a signal of the input signal terminal to a first node under the control of the first clock signal terminal;

the first control module is connected with the first clock signal terminal, and configured to transmit a signal of the first clock signal terminal to a second node under the control of the first clock signal terminal; or the first control module is connected respectively with a first signal terminal and the first clock signal terminal, and configured to transmit a signal of the first signal terminal to the second node under the control of the first clock signal terminal;

the second control module is connected with the first clock signal terminal and the first signal terminal, and configured to transmit the signal of the first clock signal terminal to the second node under the control of the first node, and to connect the first node with a third node under the control of the first signal terminal;

the feedback and adjustment module is connected respectively with a second clock signal terminal and an output signal terminal, and configured to transmit a signal of the output signal terminal to the first node under the control of the second clock signal terminal;

the output module is connected respectively with the second clock signal terminal and a second signal terminal, and configured to transmit a signal of the second signal terminal to the output signal terminal under the control of the second node, and to transmit a signal of the second clock signal terminal to the output signal terminal under the control of the third node;

the first coupling module includes a first capacitor connected between the third node and the output signal terminal, and configured to couple the output signal terminal with a potential of the third node; and

the second coupling module includes a second capacitor connected between the second node and the second signal terminal, and configured to stabilize a potential of the second node.

Correspondingly an embodiment of the invention further provides a display panel including a number N of the shift register elements according to any one of the embodiments of the invention, which are cascaded, wherein:

the output signal terminal of each of the other stages of shift register elements than the last stage of shift register element is connected with the input signal terminal of a next stage of shift register element thereto.

Correspondingly an embodiment of the invention further provides a method for driving the shift register element according to any one of the embodiments of the invention, the method including:

in an initialization phase, providing the input signal terminal with a second level signal, providing the first clock signal terminal with a first level signal and the second level signal sequentially, providing the second clock signal terminal with the second level signal and the first level signal sequentially, and outputting the second level signal from the output signal terminal;

in a pull-up phase, providing the input signal terminal and the first clock signal terminal with the first level signal, providing the second clock signal terminal with the second level signal, and outputting the second level signal from the output signal terminal;

in a shift phase, providing the input signal terminal and the first clock signal terminal with the second level signal, providing the second clock signal terminal with the first level signal, and outputting the first level signal from the output signal terminal; and

in a pull-down phase, providing the input signal terminal with the second level signal, providing the first clock signal terminal with the first level signal and the second level signal alternately, providing the second clock signal terminal with the second level signal and the first level signal alternately, and outputting the second level signal from the output signal terminal.

Advantageous effects of the invention are as follows:

In the shift register element, the method for driving the same, and the display panel according to the embodiments of the invention, the shift register element includes the input module, the first control module, the second control module, the feedback and adjustment module, the output module, the first coupling module, and the second coupling module; the feedback and adjustment module feeds the signal of the output signal terminal back to the first node under the control of the second clock signal terminal, and the second control module connects the first node with the third node under the control of the first signal, so as to shorten a period of time for which the third node is floating; and the first control module provides the second node with the signal of the first clock signal terminal or the first signal terminal under the control of the first clock signal terminal so as to shorten a period of time for which the second node is floating. Since there are the shorter periods of time for which the second node and the third node are floating respectively, and the circuit is free of the problem of node potential contention, the shift register element can be highly robust against interference, output more stably, and have a larger process window. Moreover since there are two clock signal terminals in the shift register element, there will be a smaller number of clock signals as needed, so that less wiring may be deployed, thus facilitating a design with a narrow frame edge.

### BRIEF DESCRIPTION OF THE DRAWINGS

FIG. 1A is a conventional schematic structural diagram of a shift register element;

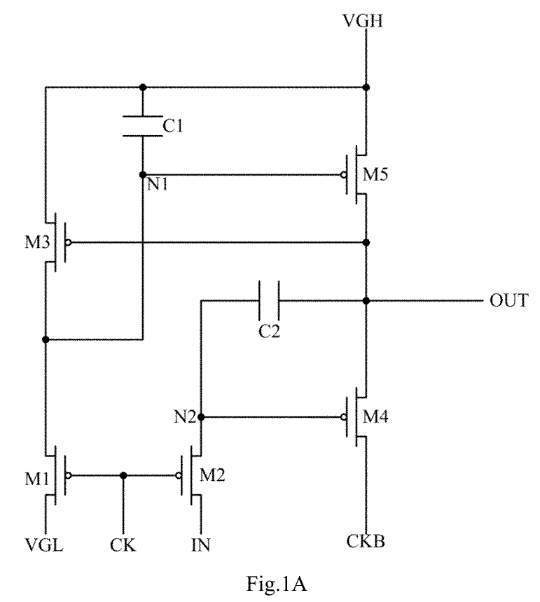

FIG. 1B is a circuit timing diagram corresponding to the shift register element as illustrated in FIG. 1A;

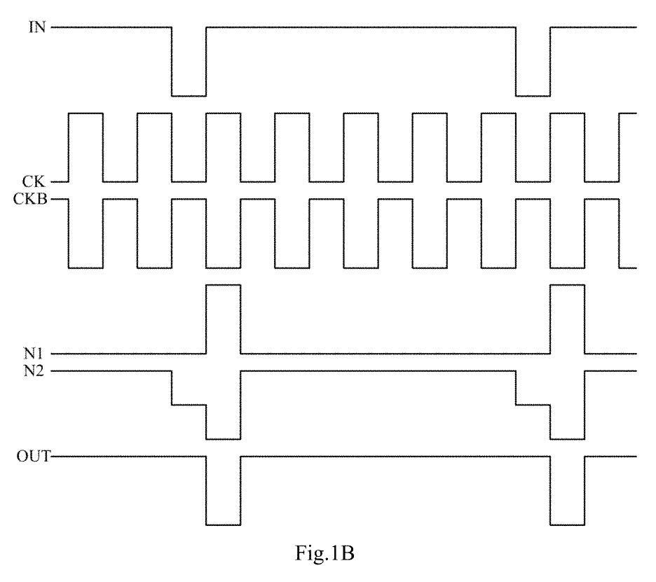

FIG. 2A is a schematic structural diagram of a shift register element in accordance with an embodiment of the invention;

FIG. 2B is a schematic structural diagram of another shift register element in accordance with an embodiment of the invention;

FIG. 3A is an exemplary schematic circuit diagram of a shift register element in accordance with an embodiment of the invention;

FIG. 3B is an exemplary schematic circuit diagram of another shift register element in accordance with an embodiment of the invention;

FIG. 4A is an exemplary schematic circuit diagram of a further shift register element in accordance with an embodiment of the invention;

FIG. 4B is an exemplary schematic circuit diagram of a further shift register element in accordance with an embodiment of the invention;

FIG. 5A is an exemplary schematic circuit diagram of a further shift register element in accordance with an embodiment of the invention;

FIG. 5B is an exemplary schematic circuit diagram of a further shift register element in accordance with an embodiment of the invention;

FIG. 6A is an exemplary schematic circuit diagram of a further shift register element in accordance with an embodiment of the invention;

FIG. 6B is an exemplary schematic circuit diagram of a further shift register element in accordance with an embodiment of the invention;

FIG. 7A is an input-output timing diagram corresponding to a shift register element in accordance with an embodiment of the invention;

FIG. 7B is another input-output timing diagram corresponding to a shift register element in accordance with an embodiment of the invention;

FIG. 8A is a schematic structural diagram of a part of a display panel in accordance with an embodiment of the invention;

FIG. 8B is an input-output timing diagram corresponding to a display panel in accordance with an embodiment of the invention;

FIG. 9 is a schematic structural diagram of two adjacent stages of shift register elements in a display panel in accordance with an embodiment of the invention;

FIG. 10 is a schematic flow chart of a driving method in accordance with an embodiment of the invention; and

FIG. 11 is a schematic structural diagram of a display device in accordance with an embodiment of the invention.

### DETAILED DESCRIPTION

In order to make the objectives, technical solutions, and advantages of the invention more apparent, the invention will be described below in further details with reference to the drawings, and apparently the embodiments to be described below are only a part but not all of the embodiments of the invention. Based upon the embodiments here of the invention, all the other embodiments which can occur to those ordinarily skilled in the art without any inventive effort shall fall into the scope of the invention as claimed.

The shapes and sizes of respective components in the drawings are not intended to reflect their real proportions, but only intended to illustrate the disclosure of the invention.

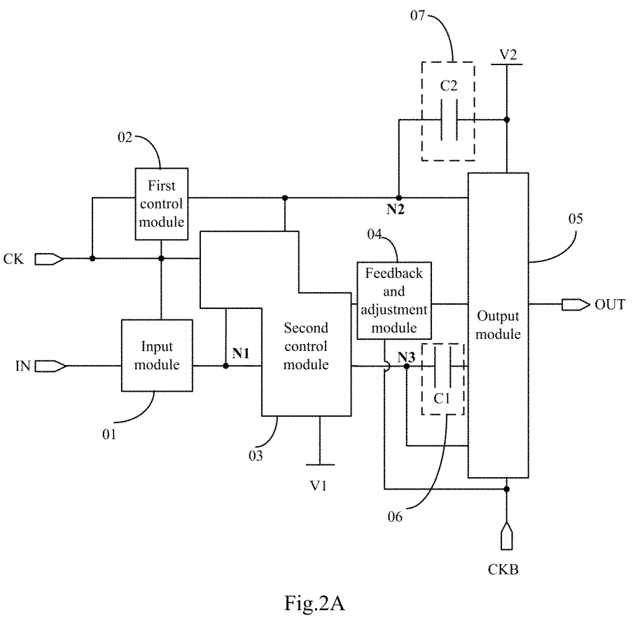

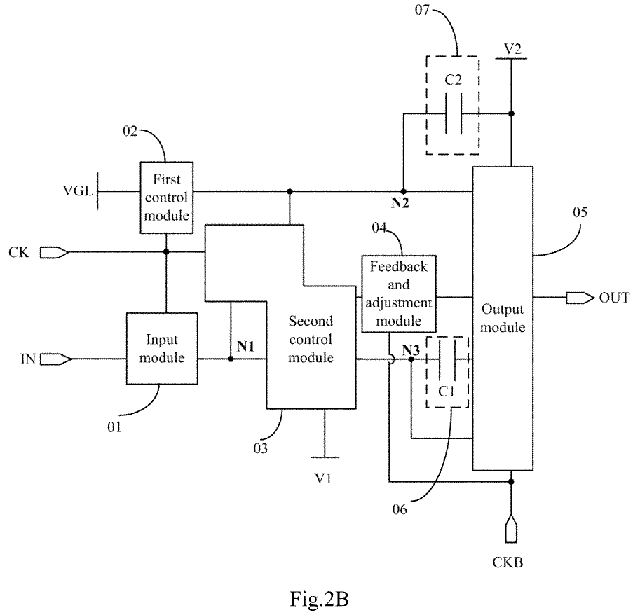

A shift register element in accordance with an embodiment of the invention is as illustrated in FIG. 2A and FIG. 2B, where FIG. 2A is a schematic structural diagram of a shift register element in accordance with an embodiment of the invention; and FIG. 2B is a schematic structural diagram of another shift register element in accordance with an embodiment of the invention. The shift register element includes an input module 01, a first control module 02, a second control module 03, a feedback and adjustment module 04, an output module 05, a first coupling module 06, and a second coupling module 07.

The input module 01 is connected with an input signal terminal IN and a first clock signal terminal CK, and configured to transmit a signal of the input signal terminal IN to a first node N1 under the control of the first clock signal terminal CK.

As illustrated in FIG. 2A, the first control module 02 is connected with the first clock signal terminal CK, and configured to transmit a signal of the first clock signal terminal CK to a second node N2 under the control of the first clock signal terminal CK; or as illustrated in FIG. 2B, the first control module 01 is connected respectively with a first signal terminal V1 and the first clock signal terminal CK, and configured to transmit a Vref1 signal of the first signal terminal to the second node N2 under the control of the first clock signal terminal CK.

The second control module 03 is connected with the first clock signal terminal CK and the first signal terminal V1, and configured to transmit the signal of the first clock signal terminal CK to the second node N2 under the control of the first node N1, and configured to connect the first node N1 with a third node N3 under the control of the first signal terminal V1.

The feedback and adjustment module 04 is connected respectively with a second clock signal terminal CKB and an output signal terminal OUT, and configured to transmit a signal of the output signal terminal OUT to the first node N1 under the control of the second clock signal terminal CKB.

The output module 05 is connected respectively with the second clock signal terminal CKB and a second signal terminal V2, and configured to transmit a signal of the second signal terminal V2 to the output signal terminal OUT under the control of the second node N2, and to transmit a signal of the second clock signal terminal CKB to the output signal terminal OUT under the control of the third node N3.

The first coupling module 06 includes a first capacitor C1 connected between the third node N3 and the output signal terminal OUT, and configured to couple the output signal terminal OUT with a potential of the third node N3.

The second coupling module 07 includes a second capacitor C2 connected between the second node N2 and the second signal terminal V2, and configured to stabilize a potential of the second node N2.

The shift register element according to the embodiment of the invention includes the input module, the first control module, the second control module, the feedback and adjustment module, the output module, the first coupling module, and the second coupling module; the feedback and adjustment module feeds the signal of the output signal terminal back to the first node under the control of the second clock signal terminal, and the second control module connects the first node with the third node under the control of the first signal, so as to shorten a period of time for which the third node is floating; and the first control module provides the second node with the signal of the first clock signal terminal or the first signal terminal under the control of the first clock signal terminal, so as to shorten a period of time for which the second node is floating. Since there are the shorter periods of time for which the second node and the third node are floating respectively, and the circuit is free of the problem of node potential contention, the shift register element can be highly robust against interference, output more stably, and have a larger process window. Moreover since there are two clock signal terminals in the shift register element, there will be a smaller number of clock signals as needed, so that less wiring may be deployed, thus facilitating a design with a narrow frame edge.

The invention will be described below in details in connection with specific embodiments thereof. It shall be noted that these embodiments are intended to better describe but not to limit the invention.

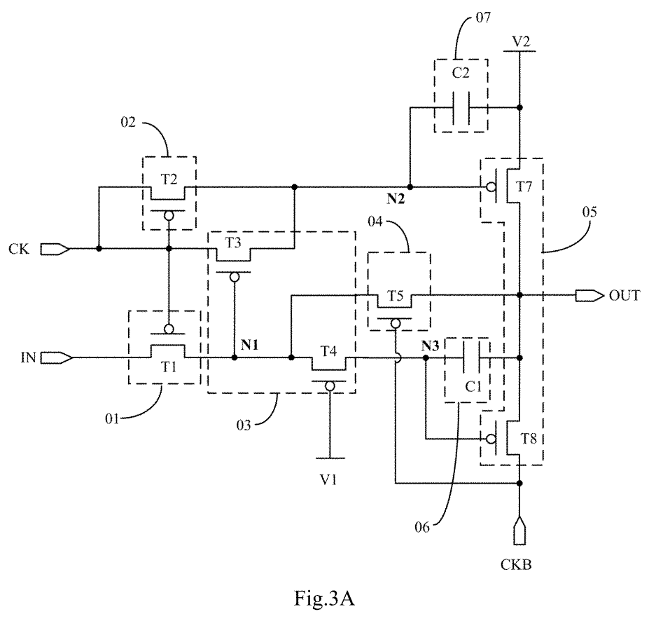

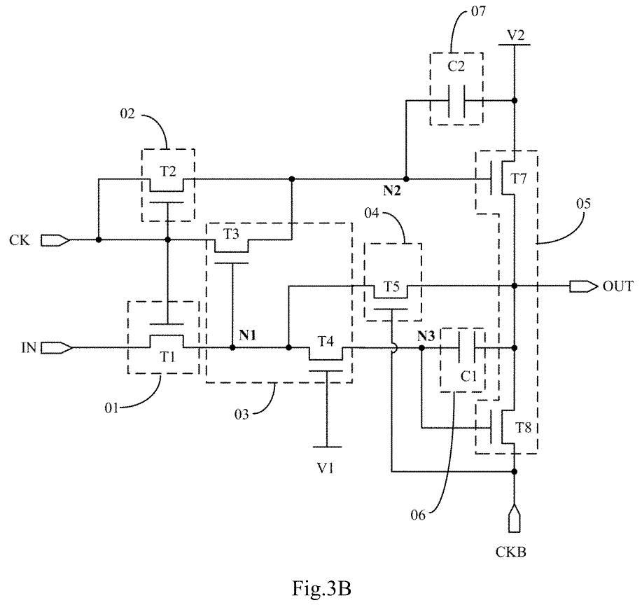

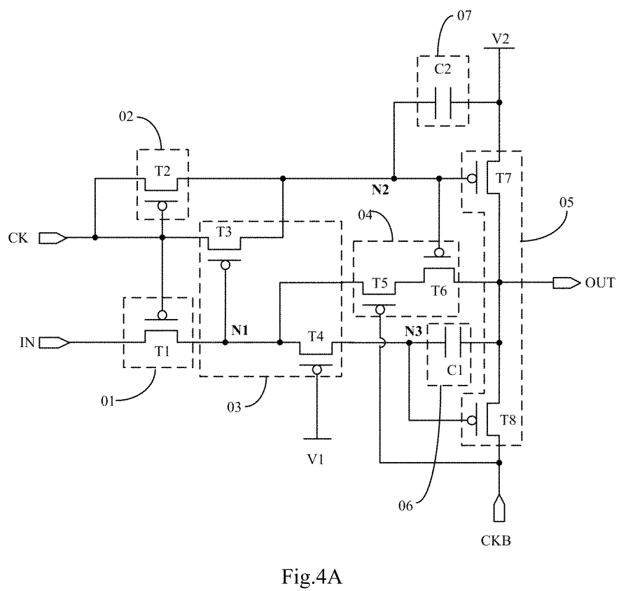

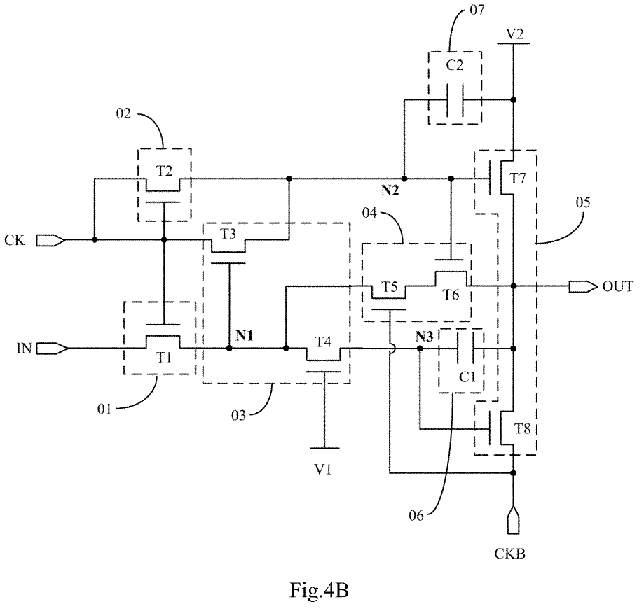

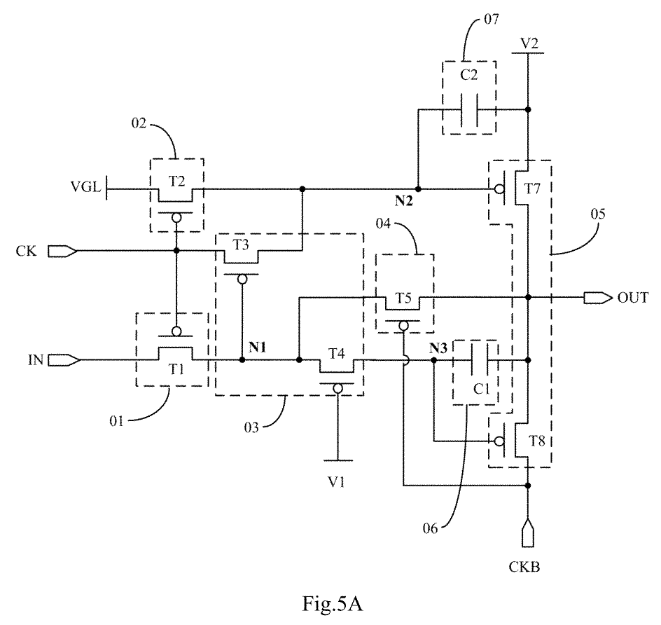

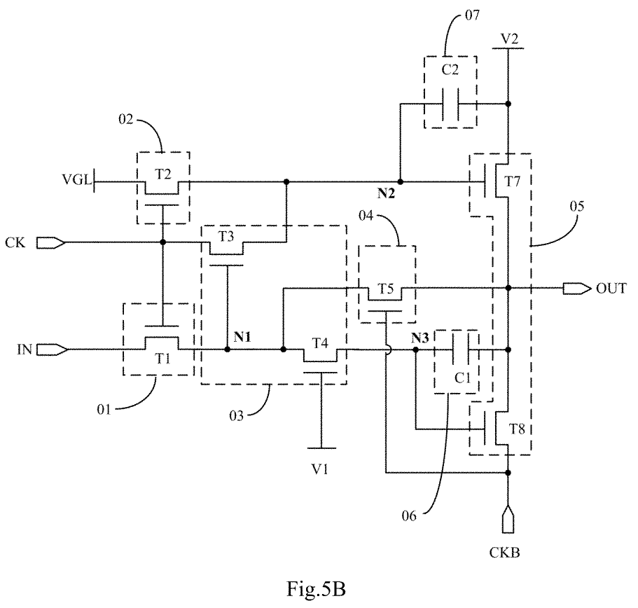

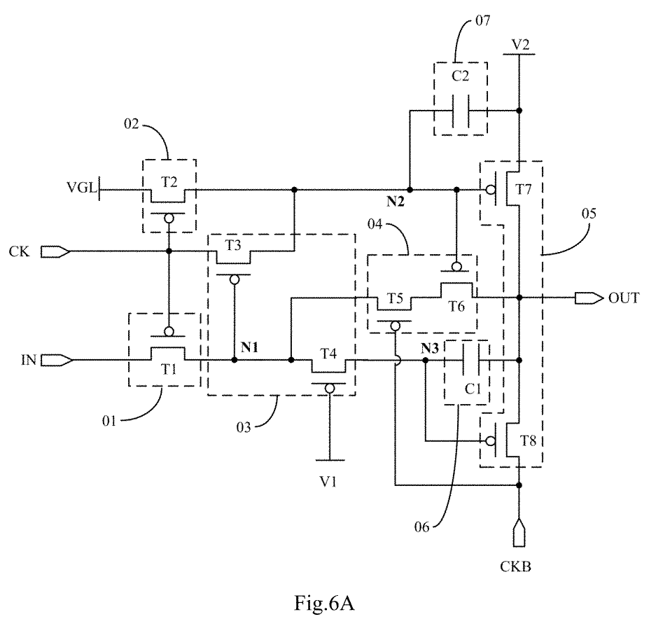

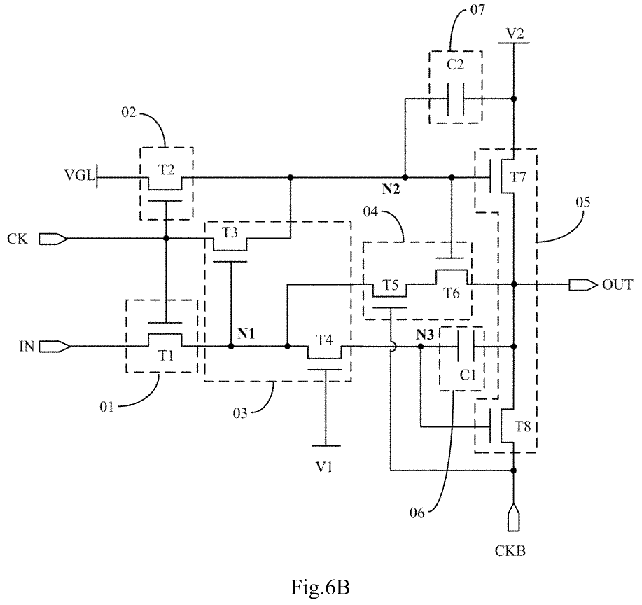

Optionally in the shift register element according to an embodiment of the invention, FIG. 3A is an exemplary schematic circuit diagram of a shift register element in accordance with an embodiment of the invention; FIG. 3B is an exemplary schematic circuit diagram of another shift register element in accordance with an embodiment of the invention; FIG. 4A is an exemplary schematic circuit diagram of a further shift register element in accordance with an embodiment of the invention; FIG. 4B is an exemplary schematic circuit diagram of a further shift register element in accordance with an embodiment of the invention; FIG. 5A is an exemplary schematic circuit diagram of a further shift register element in accordance with an embodiment of the invention; FIG. 5B is an exemplary schematic circuit diagram of a further shift register element in accordance with an embodiment of the invention; FIG. 6A is an exemplary schematic circuit diagram of a further shift register element in accordance with an embodiment of the invention; and FIG. 6B is an exemplary schematic circuit diagram of a further shift register element in accordance with an embodiment of the invention. The input module 01 includes a first transistor T1.

The first transistor T1 has a gate connected with the first clock signal terminal CK, a first pole connected with the input signal terminal IN, and a second pole connected with the first node N1.

Specifically when the first transistor T1 is turned on under the control of the first clock signal terminal CK, a signal of the input signal terminal IN is transmitted to the first node N1 through the first transistor T1 which is turned on.

The specific structure of the input module in the shift register element has been described above only by way of an example, and the specific structure of the input module in an exemplary implementation will not be limited to the structure above according to the embodiment of the invention, but can be another structure known to those skilled in the art, so the embodiment of the invention will not be limited thereto.

Optionally in the shift register element according to an embodiment of the invention, as illustrated in FIG. 3A to FIG. 6B, the first control module 02 includes a second transistor T2.

As illustrated in FIG. 3A to FIG. 4B, the second transistor T2 has a gate connected with the first clock signal terminal CK, a first pole connected with the first clock signal terminal CK, and a second pole connected with the second pole N2.

Specifically when the second transistor T2 is turned on under the control of the first clock signal terminal CK, the signal of the first clock signal terminal CK is transmitted to the second node N2 through the second transistor T2 which is turned on. The first clock signal terminal CK also has the gate of the second transistor T2 connected with the first pole thereof so that the second transistor T2 is structured into a diode, where a P-type diode only allows a low level to be written into the second node N2 while avoiding a high level from being written into the second node N2; and an N-type diode only allows a high level to be written into the second node N2 while avoiding a low level from being written into the second node N2.

Or as illustrated in FIG. 5A to FIG. 6B, the gate of the second transistor T2 is connected with the first clock signal terminal CK, the first pole of the second transistor T2 is connected with the first signal terminal V1, and the second pole of the second transistor T2 is connected with the second node N2.

Specifically when the second transistor T2 is turned on under the control of the first clock signal terminal CK, the signal of the first signal terminal V1 is transmitted to the second node N2 though the second transistor T2 which is turned on.

The specific structure of the first control module in the shift register element has been described above only by way of an example, and the specific structure of the first control module in an exemplary implementation will not be limited to the structure above according to the embodiment of the invention, but can be another structure known to those skilled in the art, so the embodiment of the invention will not be limited thereto.

Optionally in the shift register element according to an embodiment of the invention, as illustrated in FIG. 3A to FIG. 6B, the second control module 03 includes a third transistor T3 and a fourth transistor T4.

The third transistor T3 has a gate connected with the first node N1, a first pole connected with the first clock signal terminal, and a second pole connected with the second node N2.

The fourth transistor T4 has a gate connected with the first signal terminal V1, a first pole connected with the first node N1, and a second pole connected with the third node N3.

Specifically when the third transistor T3 is turned on under the control of the first node N1, the signal of the first clock signal terminal CK is transmitted to the second node N2 through the third transistor T3 which is turned on. When the fourth transistor T4 is turned on under the control of the first signal terminal V1, the first node N1 is connected with the third node N3 through the fourth transistor T4 which is turned on.

The specific structure of the second control module in the shift register element has been described above only by way of an example, and the specific structure of the second control module in an exemplary implementation will not be limited to the structure above according to the embodiment of the invention, but can be another structure known to those skilled in the art, so the embodiment of the invention will not be limited thereto.

Optionally in the shift register element according to an embodiment of the invention, as illustrated in FIG. 3A to FIG. 6B, the feedback and adjustment module 04 includes a fifth transistor T5.

The fifth transistor T5 has a gate connected with the second clock signal terminal CKB, a first pole connected with the output signal terminal OUT, and a second pole connected with the first node N1.

Specifically when the fifth transistor T5 is turned on under the control of the second clock signal terminal CKB, the signal of the output signal terminal OUT is fed back to the first node N1 through the fifth transistor T5 which is turned on.

Optionally in the shift register element according to an embodiment of the invention, as illustrated in FIG. 4A, FIG. 4B, FIG. 6A and FIG. 6B, the feedback and adjustment module 04 further includes a sixth transistor T6 connected between the first pole of the fifth transistor T5, and the output signal terminal OUT.

The sixth transistor T6 has a gate connected with the second node N2, a first pole connected with the output signal terminal OUT, and a second pole connected with the first pole of the fifth transistor T5.

In this way, when the output signal terminal OUT outputs an active signal, then the second node N2 will control the sixth transistor T6 to be turned off, so that the signal of the output signal terminal OUT can not be transmitted to the third node N3 through the fifth transistor T5 to thereby protect the potential of the third node N3 from being affected by the signal of the output signal terminal OUT so as to guarantee the stability of the output.

The specific structure of the feedback and adjustment module in the shift register element has been described above only by way of an example, and the specific structure of the feedback and adjustment module in an exemplary implementation will not be limited to the structure above according to the embodiment of the invention, but can be another structure known to those skilled in the art, so the embodiment of the invention will not be limited thereto.

Optionally in the shift register element according to an embodiment of the invention, as illustrated in FIG. 3A to FIG. 6B, the output module 05 includes a seventh transistor T7 and an eighth transistor T8.

The seventh transistor T7 has a gate connected with the second node N2, a first pole connected with the second signal terminal V2, and a second pole connected with the output signal terminal OUT.

The eighth transistor T8 has a gate connected with the third node N3, a first pole connected with the second clock signal terminal CKB, and a second pole connected with the output signal terminal OUT.

Specifically when the seventh transistor T7 is turned on under the control of the second node N2, the signal of the second signal terminal V2 is transmitted to the output signal terminal OUT through the seventh transistor T7 which is turned on. When the eight transistor T8 is turned on under the control of the third node N3, the signal of the second clock signal terminal CKB is transmitted to the output signal terminal OUT through the eighth transistor T8 which is turned on.

The specific structure of the output module in the shift register element has been described above only by way of an example, and the specific structure of the output module in an exemplary implementation will not be limited to the structure above according to the embodiment of the invention, but can be another structure known to those skilled in the art, so the embodiment of the invention will not be limited thereto.

Specifically in order to fabricate the transistors in the same process, all the transistors in the shift register element according to the embodiments of the invention are P-type transistors as illustrated in FIG. 3A, FIG. 4A, FIG. 5A, and FIG. 6A, or N-type transistors as illustrated in FIG. 3B, FIG. 4B, FIG. 5B, and FIG. 6B.

It shall be noted that in the shift register element according to an embodiment of the invention, when all the transistors are P-type transistors, then the signal of the first signal terminal may be a low-level signal, and the signal of the second signal terminal may be a high-level signal; and when all the transistors are N-type transistors, then the signal of the first signal terminal may be a high-level signal, and the signal of the second signal terminal may be a low-level signal.

Specifically in the shift register element according to an embodiment of the invention, an N-type transistor is turned on by a high-level signal, and turned off by a low-level signal; and a P-type transistor is turned on by a low-level signal, and turned off by a high-level signal.

Specifically in the shift register element according to an embodiment of the invention, a first pole of a transistor may be a source, and a second pole thereof may be a drain; or a first pole of a transistor may be a drain, and a second pole thereof may be a source, without departing from the scope of the invention as claimed.

An operating process of the shift register element according to an embodiment of the invention will be described below in connection with a circuit timing diagram thereof. In the following description, 1 represents a high level, and 0 represents a low level. It shall be noted that 1 and 0 which are logic potentials are only intended to better describe the specific operating process in the embodiment of the invention, but not to suggest any specific voltage values.

### First Example

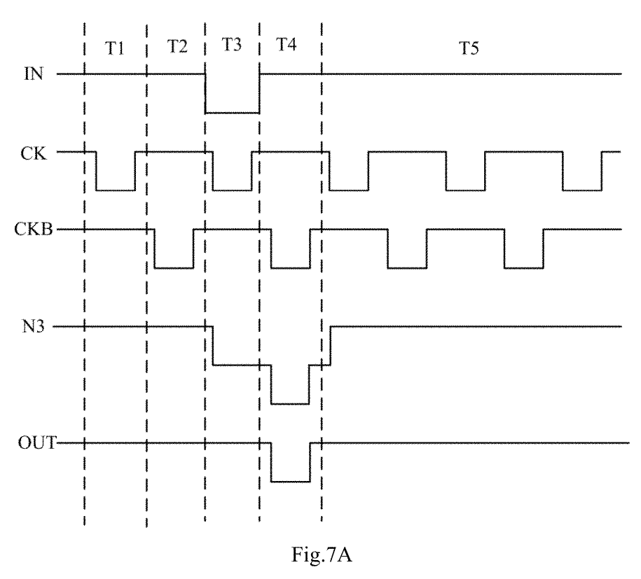

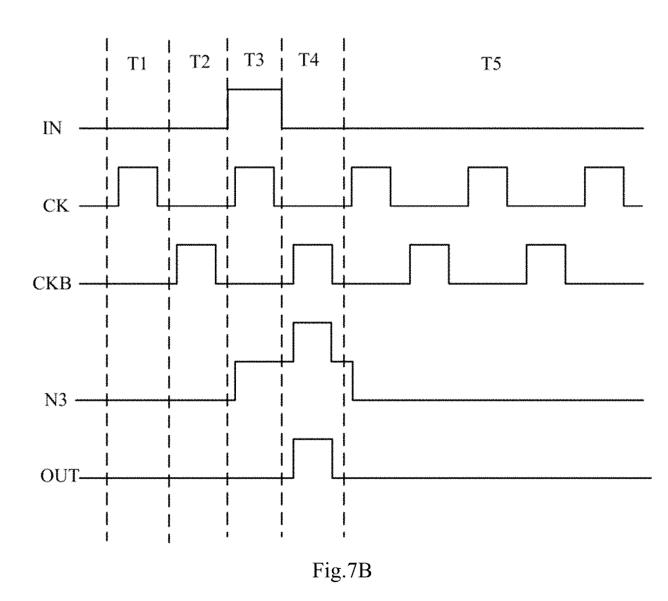

Taking the shift register element as illustrated in FIG. 3A and FIG. 5A, all the transistors in the shift register element are P-type transistors, and FIG. 7A illustrates an input-output timing diagram corresponding thereto. FIG. 7A is an input-output timing diagram corresponding to a shift register element according to an embodiment of the invention; and specifically the timing diagram shows five phases T1, T2, T3, T4, and T5 in the input-output timing diagram as illustrated in FIG. 7A.

In the T1 phase, IN=1, CK=0, and CKB=1.

With CK=0, the first transistor T1 and the second transistor T2 are turned on; with CKB=1, the fifth transistor T5 is turned off; and with the first signal terminal V1 at a low level, the fourth transistor T4 is turned on. The first transistor T1 which is turned on transmits the high-level signal of the input signal terminal IN to the first node N1, so the first node N1 is at a high level, and the third transistor T3 is turned off; the high level of the first node N1 is transmitted to the third node N3 through the fourth transistor T4 which is turned on, so the third node N3 is at a high level, and the eighth transistor T8 is turned off; the low-level signal of the first clock signal terminal CK (in the shift register element as illustrated in FIG. 3A) or the first signal terminal V1 (in the shift register element as illustrated in FIG. 5A) is transmitted to the second node N2 through the second transistor T2 which is turned on, so the second node N2 is at a low level, and the seventh transistor T7 is turned on; and the high-level signal of the second signal terminal V2 is transmitted to the output signal terminal OUT through the seventh transistor T7 which is turned on, so the output signal terminal OUT outputs a high-level signal.

In this phase, both the first node N1 and the third node N3 receive the high-level signals to thereby initialize their node potentials; and the second node N2 receives the low-level signal to thereby stabilize its node voltage in the circuit, thus resulting in a larger process window of the circuit.

In the T2 phase, IN=1, CK=1, and CKB=0.

With CK=1, the first transistor T1 and the second transistor T2 are turned off; k with CKB=0, the fifth transistor T5 is turned on; and with the first signal terminal V1 at a low level, the fourth transistor T4 is turned on. The fifth transistor T5 which is turned on feeds the high level of the output signal terminal OUT back to the first node N1, so the first node N1 is at a high level, and the third transistor T3 is turned off; the high level of the first node N1 is transmitted to the third node N3 through the fourth transistor T4 which is turned on, so the third node N3 is at a high level, and the eighth transistor T8 is turned off; the second node N2 remains at a low level due to the second capacitor C2, so the seventh transistor T7 is turned on; and the high-level signal of the second signal terminal V2 is transmitted to the output signal terminal OUT through the seventh transistor T7 which is turned on, so the output signal terminal OUT outputs a high-level signal.

In this phase, the first node N1 and the third node N3 receive the high level of the output signal terminal OUT, fed back by the fifth transistor T5, to thereby initialize their node potentials; and the node voltage in the circuit is stabilized, thus resulting in a larger process window of the circuit.

In the T3 phase, IN=0, CK=0, and CKB=1.

With CK=0, the first transistor T1 and the second transistor T2 are turned on; with CKB=1, the fifth transistor T5 is turned off; and with the first signal terminal V1 at a low level, the fourth transistor T4 is turned on. The first transistor T1 which is turned on transmits the low-level signal of the input signal terminal IN to the first node N1, so the first node N1 is at a low level, and the third transistor T3 is turned on; the low level of the first node N1 is transmitted to the third node N3 through the fourth transistor T4 which is turned on, so the third node N3 is at a low level, and the eighth transistor T8 is turned on; the low-level signal of the first clock signal terminal CK (in the shift register element as illustrated in FIG. 3A) or the first signal terminal V1 (in the shift register element as illustrated in FIG. 5A) is transmitted to the second node N2 through the second transistor T2 which is turned on, so the second node N2 is at a low level, and the seventh transistor T7 is turned on; and the high-level signal of the second signal terminal V2 is transmitted to the output signal terminal OUT through the seventh transistor T7 which is turned on, and the high-level signal of the second clock signal terminal CKB is transmitted to the output signal terminal OUT through the eight transistor T8 which is turned on, so the output signal terminal OUT outputs a high-level signal.

In this phase, all of the first node N1, the second node N2, and the third node N3 receive the low-level signals to prepare for a shift in the next phase.

In the T4 phase, IN=1, CK=1, and CKB=0.

With CK=1, the first transistor T1 and the second transistor T2 are turned off; and with the first signal terminal V1 at a low level, the fourth transistor T4 is turned on. Due to the first capacitor C1, the third node N3 remains at a low level, and the eighth transistor T8 is turned on; the low-level signal of the second clock signal terminal CKB is transmitted to the output signal terminal OUT through the eighth transistor T8 which is turned on, so the output signal terminal OUT is changed from the high level in the previous phase to a low level in this phase, so that the third node N3 is further pulled down by the coupling of first capacitor C1, and the coupling of the capacitor at the gate of the eighth transistor T8, thus enabling the eighth transistor T8 to be controlled by the third node n3 to be completely turned on, and avoiding an inaccurate output of the output signal terminal due to a threshold loss of the eighth transistor T8; the low level of the third node N3 is transmitted to the first node N1 through the fourth transistor T4 which is turned on, so the first node N1 is at a low level, and the third transistor T3 is turned on; and the high-level signal of the first clock signal terminal CK is transmitted to the second node N2 through the third transistor T3 which is turned on, so the second node N2 is at a high level, and the seventh transistor T7 is turned off.

In this phase, the fourth transistor T4 can function to alleviate drain current of the third node N3. Moreover at the instance of time when the third node N3 is further pulled down, the potential of the first node N1 is lower than the original potential thereof due to a parasitic capacitor of the fourth transistor T4, so although the second clock signal CKB is at a low level in this phase, the threshold condition of the fifth transistor T5 may not be satisfied, that is, Vsg<|Vth|, where Vsg represents the difference in voltage between the second pole of the fifth transistor T5, and the gate thereof, and Vth represents a threshold voltage of the fifth transistor T5, so the fifth transistor T5 is turned off, and the third node N3 can remain at a very low potential, so that there will be a complete low-level signal at the output signal terminal OUT, thus enabling the signal to be shifted; and there will be no node potential contention in this phase, so there will be a more stable output than the existing shift register element.

In the T5 phase, IN=1, CK=0, and CKB=1; or IN=1, CK=1, and CKB=0.

In the case that IN=1, CK=0, and CKB=1, with CK=0, the first transistor T1 and the second transistor T2 are turned on; with CKB=1, the fifth transistor T5 is turned off; and with the first signal terminal V1 at a low level, the fourth transistor T4 is turned on. The first transistor T1 which is turned on transmits the high-level signal of the input signal terminal IN to the first node N1, so the first node N1 is at a high level, and the third transistor T3 is turned off; the high level of the first node N1 is transmitted to the third node N3 through the fourth transistor T4 which is turned on, so the third node N3 is at a high level, and the eighth transistor T8 is turned off; the low-level signal of the first clock signal terminal CK (in the shift register element as illustrated in FIG. 3A) or the first signal terminal V1 (in the shift register element as illustrated in FIG. 5A) is transmitted to the second node N2 through the second transistor T2 which is turned on, so the second node N2 is at a low level, and the seventh transistor T7 is turned on; and the high-level signal of the second signal terminal V2 is transmitted to the output signal terminal OUT through the seventh transistor T7 which is turned on, so the output signal terminal OUT outputs a high-level signal.

In the case that IN=1, CK=1, and CKB=0, with CK=1, the first transistor T1 and the second transistor T2 are turned off; with CKB=0, the fifth transistor T5 is turned on; and with the first signal terminal V1 at a low level, the fourth transistor T4 is turned on. The fifth transistor T5 which is turned on feeds the high level of the output signal terminal OUT back to the first node N1, so the first node N1 is at a high level, and the third transistor T3 is turned off; the high level of the first node N1 is transmitted to the third node N3 through the fourth transistor T4 which is turned on, so the third node N3 is at a high level, and the eighth transistor T8 is turned off; the second node N2 remains at a low level due to the second capacitor C2, so the seventh transistor T7 is turned on; and the high-level signal of the second signal terminal V2 is transmitted to the output signal terminal OUT through the seventh transistor T7 which is turned on, so the output signal terminal OUT outputs a high-level signal.

This phase is maintained until a low-level signal is input to the input signal terminal in a next frame. This phase is a phase in which a high level is being output after the signal is shifted, the eighth transistor T8 remains being turned off, and the seventh transistor T7 remains being turned on, until a low-level signal is input to the input signal terminal in a next frame. Moreover in this phase, the first transistor T1 and the second transistor T2 are controlled by the first clock signal terminal CK to be turned on, at an interval of half the periodicity to write the high-level signal of the input signal terminal IN into the third node N3, and the low-level signal thereof into the second node N2 respectively; and the second clock signal terminal CKB feeds the high-level signal of the output signal terminal OUT back to the first node N1 and the third node N3 at an interval of half the periodicity to thereby avoid the third node N3 from floating, where the high level is written into the third node N3 over the two paths to thereby enable the eighth transistor T8 to be turned off, thus resulting in a more stable state of the circuit.

### Second Example

Taking the shift register element as illustrated in FIG. 4A and FIG. 6A, all the transistors in the shift register element are P-type transistors, and FIG. 7A illustrates an input-output timing diagram corresponding thereto. FIG. 7A is an input-output timing diagram corresponding to a shift register element according to an embodiment of the invention; and specifically the timing diagram shows five phases T1, T2, T3, T4, and T5 in the input-output timing diagram as illustrated in FIG. 7A.

Specifically the shift register element as illustrated in FIG. 4A includes the sixth transistor in addition to the components in the shift register element as illustrated in FIG. 3A, and the shift register element as illustrated in FIG. 6A includes the sixth transistor in addition to the components in the shift register element as illustrated in FIG. 5A, so their specific operating principles are substantially the same.

In the T1 phase, IN=1, CK=0, and CKB=1.

With CK=0, the first transistor T1 and the second transistor T2 are turned on; with CKB=1, the fifth transistor T5 is turned off; and with the first signal terminal V1 at a low level, the fourth transistor T4 is turned on. The first transistor T1 which is turned on transmits the high-level signal of the input signal terminal IN to the first node N1, so the first node N1 is at a high level, and the third transistor T3 is turned off; the high level of the first node N1 is transmitted to the third node N3 through the fourth transistor T4 which is turned on, so the third node N3 is at a high level, and the eighth transistor T8 is turned off; the low-level signal of the first clock signal terminal CK (in the shift register element as illustrated in FIG. 4A) or the first signal terminal V1 (in the shift register element as illustrated in FIG. 6A) is transmitted to the second node N2 through the second transistor T2 which is turned on, so the second node N2 is at a low level, and the seventh transistor T7 and the sixth transistor T6 are turned on; and the high-level signal of the second signal terminal V2 is transmitted to the output signal terminal OUT through the seventh transistor T7 which is turned on, so the output signal terminal OUT outputs a high-level signal.

In this phase, both the first node N1 and the third node N3 receive the high-level signals to thereby initialize their node potentials; and the second node N2 receives the low-level signal to thereby stabilize its node voltage in the circuit, thus resulting in a larger process window of the circuit.

In the T2 phase, IN=1, CK=1, and CKB=0.

With CK=1, the first transistor T1 and the second transistor T2 are turned off; with CKB=0, the fifth transistor T5 is turned on; and with the first signal terminal V1 at a low level, the fourth transistor T4 is turned on. The second node N2 remains at a low level due to the second capacitor C2, so the seventh transistor T7 and the sixth transistor T6 are turned on; and the fifth transistor T5 and the sixth transistor T6 which are turned on feed the high level of the output signal terminal OUT back to the first node N1, so the first node N1 is at a high level, and the third transistor T3 is turned off; the high level of the first node N1 is transmitted to the third node N3 through the fourth transistor T4 which is turned on, so the third node N3 is at a high level, and the eighth transistor T8 is turned off; and the high-level signal of the second signal terminal V2 is transmitted to the output signal terminal OUT through the seventh transistor T7 which is turned on, so the output signal terminal OUT outputs a high-level signal.

In this phase, the first node N1 and the third node N3 receive the high level of the output signal terminal OUT, fed back by the fifth transistor T5 and the sixth transistor T6, to thereby initialize their node potentials; and the node voltage in the circuit is stabilized, thus resulting in a larger process window of the circuit.

In the T3 phase, IN=0, CK=0, and CKB=1.

With CK=0, the first transistor T1 and the second transistor T2 are turned on; with CKB=1, the fifth transistor T5 is turned off; and with the first signal terminal V1 at a low level, the fourth transistor T4 is turned on. The first transistor T1 which is turned on transmits the low-level signal of the input signal terminal IN to the first node N1, so the first node N1 is at a low level, and the third transistor T3 is turned on; the low level of the first node N1 is transmitted to the third node N3 through the fourth transistor T4 which is turned on, so the third node N3 is at a low level, and the eighth transistor T8 is turned on; the low-level signal of the first clock signal terminal CK (in the shift register element as illustrated in FIG. 4A) or the first signal terminal V1 (in the shift register element as illustrated in FIG. 6A) is transmitted to the second node N2 through the second transistor T2 which is turned on, so the second node N2 is at a low level, and the seventh transistor T7 and the sixth transistor T6 are turned on; and the high-level signal of the second signal terminal V2 is transmitted to the output signal terminal OUT through the seventh transistor T7 which is turned on, and the high-level signal of the second clock signal terminal CKB is transmitted to the output signal terminal OUT through the eight transistor T8 which is turned on, so the output signal terminal OUT outputs a high-level signal.

In this phase, all of the first node N1, the second node N2, and the third node N3 receive the low-level signals to prepare for a shift in the next phase.

In the T4 phase, IN=1, CK=1, and CKB=0.

With CK=1, the first transistor T1 and the second transistor T2 are turned off; and with the first signal terminal V1 at a low level, the fourth transistor T4 is turned on. Due to the first capacitor C1, the third node N3 remains at a low level firstly, and the eighth transistor T8 is turned on; the low-level signal of the second clock signal terminal CKB is transmitted to the output signal terminal OUT through the eighth transistor T8 which is turned on, so the output signal terminal OUT is changed from the high level in the previous phase to a low level in this phase, so that the third node N3 is further pulled down by the coupling of first capacitor C1, and he coupling of the capacitor at the gate of the eighth transistor T8, thus enabling the eighth transistor T8 to be controlled by the third node n3 to be completely turned on, and avoiding an inaccurate output of the output signal terminal due to a threshold loss of the eighth transistor T8; the low level of the third node N3 is transmitted to the first node N1 through the fourth transistor T4 which is turned on, so the first node N1 is at a low level, and the third transistor T3 is turned on; and the high-level signal of the first clock signal terminal CK is transmitted to the second node N2 through the third transistor T3 which is turned on, so the second node N2 is at a high level, and the seventh transistor T7 and the sixth transistor T6 are turned off.

In this phase, the fourth transistor T4 can function to alleviate drain current of the third node N3. Moreover at the instance of time when the third node N3 is further pulled down, the potential of the first node N1 is lower than the original potential thereof due to a parasitic capacitor of the fourth transistor T4, so although the second clock signal CKB is at a low level in this phase, the threshold condition of the fifth transistor T5 may not be satisfied, that is, Vsg<|Vth|, where Vsg represents the difference in voltage between the second pole of the fifth transistor T5, and the gate thereof, and Vth represents a threshold voltage of the fifth transistor T5, so the fifth transistor T5 is turned off. Since both the fifth transistor T5 and the sixth transistor T6 are turned off, no current of the output signal terminal OUT will flow to the first node N1, so that the third node N3 can remain at a very low potential, and there will be a complete low-level signal at the output signal terminal OUT, thus enabling the signal to be shifted; and there will be no node potential contention in this phase, so there will be a more stable output than the existing shift register element.

In the T5 phase, IN=1, CK=0, and CKB=1; or IN=1, CK=1, and CKB=0.

In the case that IN=1, CK=0, and CKB=1, with CK=0, the first transistor T1 and the second transistor T2 are turned on; with CKB=1, the fifth transistor T5 is turned off; and with the first signal terminal V1 at a low level, the fourth transistor T4 is turned on. The first transistor T1 which is turned on transmits the high-level signal of the input signal terminal IN to the first node N1, so the first node N1 is at a high level, and the third transistor T3 is turned off; the high level of the first node N1 is transmitted to the third node N3 through the fourth transistor T4 which is turned on, so the third node N3 is at a high level, and the eighth transistor T8 is turned off; the low-level signal of the first clock signal terminal (in the shift register element as illustrated in FIG. 4A) or the first signal terminal V1 (in the shift register element as illustrated in FIG. 6A) is transmitted to the second node N2 through the second transistor T2 which is turned on, so the second node N2 is at a low level, and the seventh transistor T7 and the sixth transistor T6 are turned on; and the high-level signal of the second signal terminal V2 is transmitted to the output signal terminal OUT through the seventh transistor T7 which is turned on, so the output signal terminal OUT outputs a high-level signal.

In the case that IN=1, CK=1, and CKB=0, with CK=1, the first transistor T1 and the second transistor T2 are turned off; with CKB=0, the fifth transistor T5 is turned on; and with the first signal terminal V1 at a low level, the fourth transistor T4 is turned on. The second node N2 remains at a low level due to the second capacitor C2, so the seventh transistor T7 and the sixth transistor T6 are turned on; the fifth transistor T5 and the sixth transistor T6, which are turned on, feed the high level of the output signal terminal OUT back to the first node N1, so the first node N1 is at a high level, and the third transistor T3 is turned off; the high level of the first node N1 is transmitted to the third node N3 through the fourth transistor T4 which is turned on, so the third node N3 is at a high level, and the eighth transistor T8 is turned off; and the high-level signal of the second signal terminal V2 is transmitted to the output signal terminal OUT through the seventh transistor T7 which is turned on, so the output signal terminal OUT outputs a high-level signal.

This phase is maintained until a low-level signal is input to the input signal terminal in a next frame. This phase is a phase in which a high level is being output after the signal is shifted, the eighth transistor T8 remains being turned off, and the seventh transistor T7 remains being turned on, until a low-level signal is input to the input signal terminal in a next frame. Moreover in this phase, the first transistor T1 and the second transistor T2 are controlled by the first clock signal terminal CK to be turned on, at an interval of half the periodicity to write the high-level signal of the input signal terminal IN into the third node N3, and the low-level signal thereof into the second node N2 respectively; and the second clock signal terminal CKB feeds the high-level signal of the output signal terminal OUT back to the first node N1 and the third node N3 at an interval of half the periodicity to thereby avoid the third node N3 from floating, where the high level is written into the third node N3 over the two paths to thereby enable the eighth transistor T8 to be turned off, thus resulting in a more stable state of the circuit.

### Third Example

Taking the shift register element as illustrated in FIG. 3B and FIG. 5B, all the transistors in the shift register element are N-type transistors, and FIG. 7B illustrates an input-output timing diagram corresponding thereto. FIG. 7A is an input-output timing diagram corresponding to a shift register element according to an embodiment of the invention; and specifically the timing diagram shows five phases T1, T2, T3, T4, and T5 in the input-output timing diagram as illustrated in FIG. 7B.

In the T1 phase, IN=0, CK=1, and CKB=0.

With CK=1, the first transistor T1 and the second transistor T2 are turned on; with CKB=0, the fifth transistor T5 is turned off; and with the first signal terminal V1 at a high level, the fourth transistor T4 is turned on. The first transistor T1 which is turned on transmits the low-level signal of the input signal terminal IN to the first node N1, so the first node N1 is at a low level, and the third transistor T3 is turned off; the low level of the first node N1 is transmitted to the third node N3 through the fourth transistor T4 which is turned on, so the third node N3 is at a low level, and the eighth transistor T8 is turned off; the high-level signal of the first clock signal terminal CK (in the shift register element as illustrated in FIG. 3B) or the first signal terminal V1 (in the shift register element as illustrated in FIG. 5B) is transmitted to the second node N2 through the second transistor T2 which is turned on, so the second node N2 is at a high level, and the seventh transistor T7 is turned on; and the low-level signal of the second signal terminal V2 is transmitted to the output signal terminal OUT through the seventh transistor T7 which is turned on, so the output signal terminal OUT outputs a low-level signal.

In this phase, both the first node N1 and the third node N3 receive the low-level signals to thereby initialize their node potentials; and the second node N2 receives the high-level signal to thereby stabilize its node voltage in the circuit, thus resulting in a larger process window of the circuit.

In the T2 phase, IN=0, CK=0, and CKB=1.

With CK=0, the first transistor T1 and the second transistor T2 are turned off; with CKB=1, the fifth transistor T5 is turned on; and with the first signal terminal V1 at a high level, the fourth transistor T4 is turned on. The fifth transistor T5 which is turned on feeds the low level of the output signal terminal OUT back to the first node N1, so the first node N1 is at a low level, and the third transistor T3 is turned off; the low level of the first node N1 is transmitted to the third node N3 through the fourth transistor T4 which is turned on, so the third node N3 is at a low level, and the eighth transistor T8 is turned off; the second node N2 remains at a high level due to the second capacitor C2, so the seventh transistor T7 is turned on; and the low-level signal of the second signal terminal V2 is transmitted to the output signal terminal OUT through the seventh transistor T7 which is turned on, so the output signal terminal OUT outputs a low-level signal.

In this phase, the first node N1 and the third node N3 receive the low level of the output signal terminal OUT, fed back by the fifth transistor T5, to thereby initialize their node potentials; and the node voltage in the circuit is stabilized, thus resulting in a larger process window of the circuit.

In the T3 phase, IN=1, CK=1, and CKB=0.

With CK=1, the first transistor T1 and the second transistor T2 are turned on; with CKB=0, the fifth transistor T5 is turned off; and with the first signal terminal V1 at a high level, the fourth transistor T4 is turned on. The first transistor T1 which is turned on transmits the high-level signal of the input signal terminal IN to the first node N1, so the first node N1 is at a high level, and the third transistor T3 is turned on; the high level of the first node N1 is transmitted to the third node N3 through the fourth transistor T4 which is turned on, so the third node N3 is at a high level, and the eighth transistor T8 is turned on; the high-level signal of the first clock signal terminal CK (in the shift register element as illustrated in FIG. 3B) or the first signal terminal V1 (in the shift register element as illustrated in FIG. 5B) is transmitted to the second node N2 through the second transistor T2 which is turned on, so the second node N2 is at a high level, and the seventh transistor T7 is turned on; and the low-level signal of the second signal terminal V2 is transmitted to the output signal terminal OUT through the seventh transistor T7 which is turned on, and the low-level signal of the second clock signal terminal CKB is transmitted to the output signal terminal OUT through the eight transistor T8 which is turned on, so the output signal terminal OUT outputs a low-level signal.

In this phase, all of the first node N1, the second node N2, and the third node N3 receive the high-level signals to prepare for a shift in the next phase.

In the T4 phase, IN=0, CK=0, and CKB=1.

With CK=0, the first transistor T1 and the second transistor T2 are turned off; and with the first signal terminal V1 at a high level, the fourth transistor T4 is turned on. Due to the first capacitor C1, the third node N3 remains at a high level, and the eighth transistor T8 is turned on; the high-level signal of the second clock signal terminal CKB is transmitted to the output signal terminal OUT through the eighth transistor T8 which is turned on, so the output signal terminal OUT is changed from the low level in the previous phase to a high level in this phase, so that the third node N3 is further pulled up by the coupling of first capacitor C1, and the coupling of the capacitor at the gate of the eighth transistor T8, thus enabling the eighth transistor T8 to be controlled by the third node N3 to be completely turned on, and avoiding an inaccurate output of the output signal terminal due to a threshold loss of the eighth transistor T8; the high level of the third node N3 is transmitted to the first node N1 through the fourth transistor T4 which is turned on, so the first node N1 is at a high level, and the third transistor T3 is turned on; and the low-level signal of the first clock signal terminal CK is transmitted to the second node N2 through the third transistor T3 which is turned on, so the second node N2 is at a low level, and the seventh transistor T7 is turned off.

In this phase, the fourth transistor T4 can function to alleviate drain current of the third node N3. Moreover at the instance of time when the third node N3 is further pulled up, the potential of the first node N1 is higher than the original potential thereof due to a parasitic capacitor of the fourth transistor T4, so although the second clock signal CKB is at a high level in this phase, the threshold condition of the fifth transistor T5 may not be satisfied, that is, Vsg<|Vth|, where Vsg represents the difference in voltage between the second pole of the fifth transistor T5, and the gate thereof, and Vth represents a threshold voltage of the fifth transistor T5, so the fifth transistor T5 is turned off, and the third node N3 can remain at a very high potential, so that there will be a complete high-level signal at the output signal terminal OUT, thus enabling the signal to be shifted; and there will be no node potential contention in this phase, so there will be a more stable output than the existing shift register element.

In the T5 phase, IN=0, CK=1, and CKB=0; or IN=0, CK=0, and CKB=1.

In the case that IN=0, CK=1, and CKB=0, with CK=1, the first transistor T1 and the second transistor T2 are turned on; with CKB=1, the fifth transistor T5 is turned off; and with the first signal terminal V1 at a high level, the fourth transistor T4 is turned on. The first transistor T1 which is turned on transmits the low-level signal of the input signal terminal IN to the first node N1, so the first node N1 is at a low level, and the third transistor T3 is turned off; the low level of the first node N1 is transmitted to the third node N3 through the fourth transistor T4 which is turned on, so the third node N3 is at a low level, and the eighth transistor T8 is turned off; the high-level signal of the first clock signal terminal (in the shift register element as illustrated in FIG. 3B) or the first signal terminal V1 (in the shift register element as illustrated in FIG. 5B) is transmitted to the second node N2 through the second transistor T2 which is turned on, so the second node N2 is at a high level, and the seventh transistor T7 is turned on; and the low-level signal of the second signal terminal V2 is transmitted to the output signal terminal OUT through the seventh transistor T7 which is turned on, so the output signal terminal OUT outputs a low-level signal.

In the case that IN=0, CK=0, and CKB=1, with CK=0, the first transistor T1 and the second transistor T2 are turned off; with CKB=1, the fifth transistor T5 is turned on; and with the first signal terminal V1 at a high level, the fourth transistor T4 is turned on. The fifth transistor T5 which is turned on feeds the low level of the output signal terminal OUT back to the first node N1, so the first node N1 is at a low level, and the third transistor T3 is turned off; the low level of the first node N1 is transmitted to the third node N3 through the fourth transistor T4 which is turned on, so the third node N3 is at a low level, and the eighth transistor T8 is turned off; the second node N2 remains at a high level due to the second capacitor C2, so the seventh transistor T7 is turned on; and the low-level signal of the second signal terminal V2 is transmitted to the output signal terminal OUT through the seventh transistor T7 which is turned on, so the output signal terminal OUT outputs a low-level signal.

This phase is maintained until a high-level signal is input to the input signal terminal in a next frame. This phase is a phase in which a low level is being output after the signal is shifted, the eighth transistor T8 remains being turned off, and the seventh transistor T7 remains being turned on, until a high-level signal is input to the input signal terminal in a next frame. Moreover in this phase, the first transistor T1 and the second transistor T2 are controlled by the first clock signal terminal CK to be turned on, at an interval of half the periodicity to write the low-level signal of the input signal terminal IN into the third node N3, and the high-level signal thereof into the second node N2 respectively; and the second clock signal terminal CKB feeds the low-level signal of the output signal terminal OUT back to the first node N1 and the third node N3 at an interval of half the periodicity to thereby avoid the third node N3 from floating, where the low level is written into the third node N3 over the two paths to thereby enable the eighth transistor T8 to be turned off, thus resulting in a more stable state of the circuit.

### Fourth Example

Taking the shift register element as illustrated in FIG. 4B and FIG. 6B, all the transistors in the shift register element are N-type transistors, and FIG. 7B illustrates an input-output timing diagram corresponding thereto. FIG. 7B is an input-output timing diagram corresponding to a shift register element according to an embodiment of the invention; and specifically the timing diagram shows five phases T1, T2, T3, T4, and T5 in the input-output timing diagram as illustrated in FIG. 7B.

Specifically the shift register element as illustrated in FIG. 4B includes the sixth transistor in addition to the components in the shift register element as illustrated in FIG. 3A, and the shift register element as illustrated in FIG. 6B includes the sixth transistor in addition to the components in the shift register element as illustrated in FIG. 5B, so their specific operating principles are substantially the same.

In the T1 phase, IN=0, CK=1, and CKB=0.

With CK=1, the first transistor T1 and the second transistor T2 are turned on; with CKB=0, the fifth transistor T5 is turned off; and with the first signal terminal V1 at a high level, the fourth transistor T4 is turned on. The first transistor T1 which is turned on transmits the low-level signal of the input signal terminal IN to the first node N1, so the first node N1 is at a low level, and the third transistor T3 is turned off; the low level of the first node N1 is transmitted to the third node N3 through the fourth transistor T4 which is turned on, so the third node N3 is at a low level, and the eighth transistor T8 is turned off; the high-level signal of the first clock signal terminal CK (in the shift register element as illustrated in FIG. 4B) or the first signal terminal V1 (in the shift register element as illustrated in FIG. 6B) is transmitted to the second node N2 through the second transistor T2 which is turned on, so the second node N2 is at a high level, and the seventh transistor T7 and the sixth transistor T6 are turned on; and the low-level signal of the second signal terminal V2 is transmitted to the output signal terminal OUT through the seventh transistor T7 which is turned on, so the output signal terminal OUT outputs a low-level signal.

In this phase, both the first node N1 and the third node N3 receive the low-level signals to thereby initialize their node potentials; and the second node N2 receives the high-level signal to thereby stabilize its node voltage in the circuit, thus resulting in a larger process window of the circuit.

In the T2 phase, IN=0, CK=0, and CKB=1.

With CK=0, the first transistor T1 and the second transistor T2 are turned off; with CKB=1, the fifth transistor T5 is turned on; and with the first signal terminal V1 at a high level, the fourth transistor T4 is turned on. The second node N2 remains at a high level due to the second capacitor C2, so the seventh transistor T7 and the sixth transistor T6 are turned on; and the fifth transistor T5 and the sixth transistor T6 which are turned on feed the low level of the output signal terminal OUT back to the first node N1, so the first node N1 is at a low level, and the third transistor T3 is turned off; the low level of the first node N1 is transmitted to the third node N3 through the fourth transistor T4 which is turned on, so the third node N3 is at a low level, and the eighth transistor T8 is turned off; and the low-level signal of the second signal terminal V2 is transmitted to the output signal terminal OUT through the seventh transistor T7 which is turned on, so the output signal terminal OUT outputs a low-level signal.

In this phase, the first node N1 and the third node N3 receive the low level of the output signal terminal OUT, fed back by the fifth transistor T5 and the sixth transistor T6, to thereby initialize their node potentials; and the node voltage in the circuit is stabilized, thus resulting in a larger process window of the circuit.

In the T3 phase, IN=1, CK=1, and CKB=0.

With CK=1, the first transistor T1 and the second transistor T2 are turned on; with CKB=0, the fifth transistor T5 is turned off; and with the first signal terminal V1 at a high level, the fourth transistor T4 is turned on. The first transistor T1 which is turned on transmits the high-level signal of the input signal terminal IN to the first node N1, so the first node N1 is at a high level, and the third transistor T3 is turned on; the high level of the first node N1 is transmitted to the third node N3 through the fourth transistor T4 which is turned on, so the third node N3 is at a high level, and the eighth transistor T8 is turned on; the high-level signal of the first clock signal terminal CK (in the shift register element as illustrated in FIG. 4B) or the first signal terminal V1 (in the shift register element as illustrated in FIG. 6B) is transmitted to the second node N2 through the second transistor T2 which is turned on, so the second node N2 is at a high level, and the seventh transistor T7 and the sixth transistor T6 are turned on; and the low-level signal of the second signal terminal V2 is transmitted to the output signal terminal OUT through the seventh transistor T7 which is turned on, and the low-level signal of the second clock signal terminal CKB is transmitted to the output signal terminal OUT through the eight transistor T8 which is turned on, so the output signal terminal OUT outputs a low-level signal.

In this phase, all of the first node N1, the second node N2, and the third node N3 receive the high-level signals to prepare for a shift in the next phase.

In the T4 phase, IN=0, CK=0, and CKB=1.

With CK=0, the first transistor T1 and the second transistor T2 are turned off; and with the first signal terminal V1 at a high level, the fourth transistor T4 is turned on. Due to the first capacitor C1, the third node N3 remains at a high level firstly, and the eighth transistor T8 is turned on; the high-level signal of the second clock signal terminal CKB is transmitted to the output signal terminal OUT through the eighth transistor T8 which is turned on, so the output signal terminal OUT is changed from the low level in the previous phase to a high level in this phase, so that the third node N3 is further pulled up by the coupling of first capacitor C1, and the coupling of the capacitor at the gate of the eighth transistor T8, thus enabling the eighth transistor T8 to be controlled by the third node N3 to be completely turned on, and avoiding an inaccurate output of the output signal terminal due to a threshold loss of the eighth transistor T8; the high level of the third node N3 is transmitted to the first node N1 through the fourth transistor T4 which is turned on, so the first node N1 is at a high level, and the third transistor T3 is turned on; and the low-level signal of the first clock signal terminal CK is transmitted to the second node N2 through the third transistor T3 which is turned on, so the second node N2 is at a low level, and the seventh transistor T7 and the sixth transistor T6 are turned off.

In this phase, the fourth transistor T4 can function to alleviate drain current of the third node N3. Moreover at the instance of time when the third node N3 is further pulled up, the potential of the first node N1 is higher than the original potential thereof due to a parasitic capacitor of the fourth transistor T4, so although the second clock signal CKB is at a high level in this phase, the threshold condition of the fifth transistor T5 may not be satisfied, that is, Vsg<|Vth|, where Vsg represents the difference in voltage between the second pole of the fifth transistor T5, and the gate thereof, and Vth represents a threshold voltage of the fifth transistor T5, so the fifth transistor T5 is turned off. Since both the fifth transistor T5 and the sixth transistor T6 are turned off, no current of the output signal terminal OUT can flow to the first node N1, so that the third node N3 can remain at a very high potential, and there will be a complete high-level signal at the output signal terminal OUT, thus enabling the signal to be shifted; and there will be no node potential contention in this phase, so there will be a more stable output than the existing shift register element.

In the T5 phase, IN=0, CK=1, and CKB=0; or IN=0, CK=0, and CKB=1.

In the case that IN=0, CK=1, and CKB=0, with CK=1, the first transistor T1 and the second transistor T2 are turned on; with CKB=0, the fifth transistor T5 is turned off and with the first signal terminal V1 at a high level, the fourth transistor T4 is turned on. The first transistor T1 which is turned on transmits the low-level signal of the input signal terminal IN to the first node N1, so the first node N1 is at a low level, and the third transistor T3 is turned off; the low level of the first node N1 is transmitted to the third node N3 through the fourth transistor T4 which is turned on, so the third node N3 is at a low level, and the eighth transistor T8 is turned off; the high-level signal of the first clock signal terminal CK (in the shift register element as illustrated in FIG. 4B) or the first signal terminal V1 (in the shift register element as illustrated in FIG. 6B) is transmitted to the second node N2 through the second transistor T2 which is turned on, so the second node N2 is at a high level, and the seventh transistor T7 and the sixth transistor T6 are turned on; and the low-level signal of the second signal terminal V2 is transmitted to the output signal terminal OUT through the seventh transistor T7 which is turned on, so the output signal terminal OUT outputs a low-level signal.

In the case that IN=0, CK=0, and CKB=1, with CK=0, the first transistor T1 and the second transistor T2 are turned off with CKB=1, the fifth transistor T5 is turned on; and with the first signal terminal V1 at a high level, the fourth transistor T4 is turned on. The second node N2 remains at a high level due to the second capacitor C2, so the seventh transistor T7 and the sixth transistor T6 are turned on; the fifth transistor T5 and the sixth transistor T6, which are turned on feed the low level of the output signal terminal OUT back to the first node N1, so the first node N1 is at a low level, and the third transistor T3 is turned off; the low level of the first node N1 is transmitted to the third node N3 through the fourth transistor T4 which is turned on, so the third node N3 is at a low level, and the eighth transistor T8 is turned off; and the low-level signal of the second signal terminal V2 is transmitted to the output signal terminal OUT through the seventh transistor T7 which is turned on, so the output signal terminal OUT outputs a low-level signal.

This phase is maintained until a high-level signal is input to the input signal terminal in a next frame. This phase is a phase in which a low level is being output after the signal is shifted, the eighth transistor T8 remains being turned off, and the seventh transistor T7 remains being turned on, until a high-level signal is input to the input signal terminal in a next frame. Moreover in this phase, the first transistor T1 and the second transistor T2 are controlled by the first clock signal terminal CK to be turned on, at an interval of half the periodicity to write the low-level signal of the input signal terminal IN into the third node N3, and the high-level signal thereof into the second node N2 respectively; and the second clock signal terminal CKB feeds the low-level signal of the output signal terminal OUT back to the first node N1 and the third node N3 at an interval of half the periodicity to thereby avoid the third node N3 from floating, where the low level is written into the third node N3 over the two paths to thereby enable the eighth transistor T8 to be turned off, thus resulting in a more stable state of the circuit.

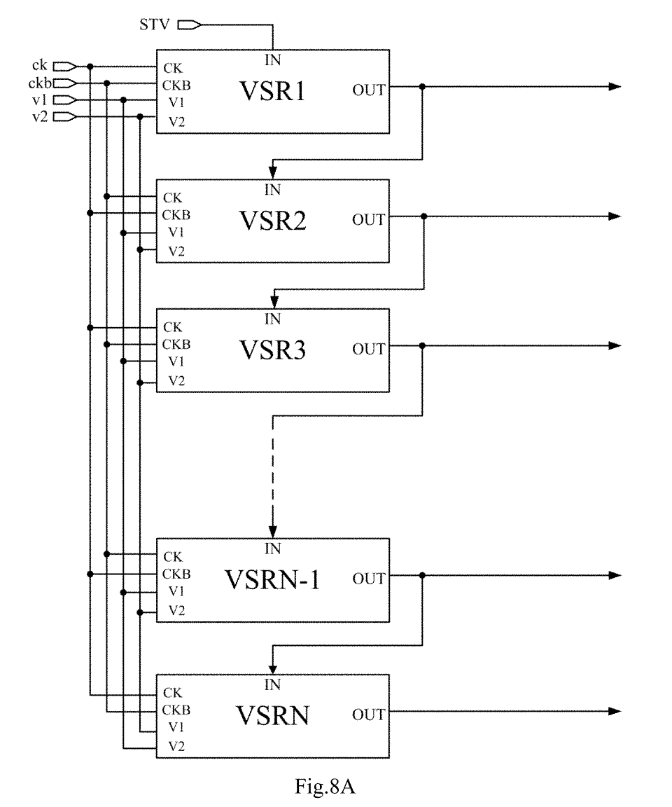

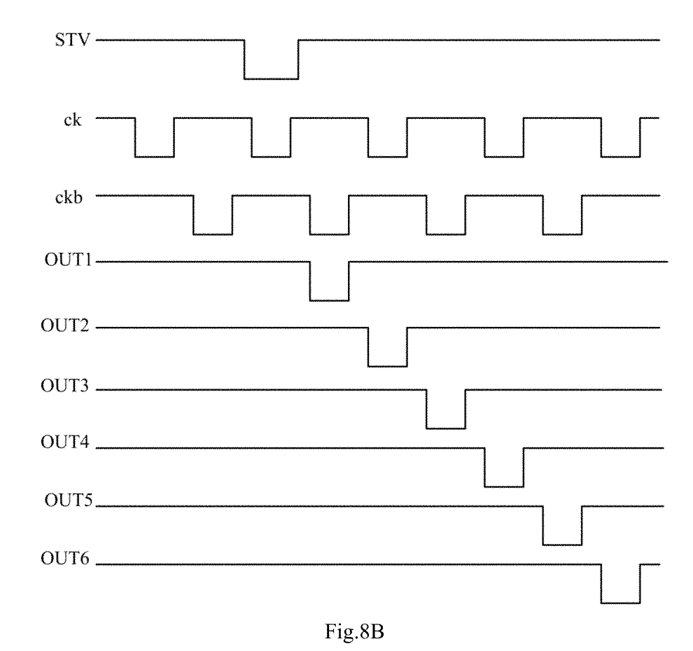

Based upon the same inventive idea, an embodiment of the invention further provides a display panel as illustrated in FIG. 8A which is a schematic structural diagram of a part of a display panel according to an embodiment of the invention, where the display panel includes N cascaded shift register elements VSR1 to VSRN according to the embodiments of the invention; and the output signal terminal OUT of each of the other stages of shift register elements VSRn than the last stage of shift register element VSRN is connected with the input signal terminal IN of a next stage of shift register element VSRn+1 thereto, where N is an integer more than 1.

In each stage of shift register element in the display panel according to the embodiment of the invention, the feedback and adjustment module feeds the signal of the output signal terminal back to the first node under the control of the second clock signal terminal, and the second control module connect the first node with the third node under the control of the first signal, so as to shorten a period of time for which the third node is floating; and the first control module provides the signal of the first clock signal terminal or the first signal terminal to the second node under the control of the first clock signal terminal, so as to shorten a period of time for which the second node is floating. Since there are the shorter periods of time for which the second node and the third node are floating respectively, and the circuit is free of the problem of node potential contention, the shift register element can be highly robust against interference, output more stably, and have a larger process window. Moreover since there are two clock signal terminals in the shift register element, there will be a smaller number of clock signals as needed, so that less wiring may be deployed, thus facilitating a design with a narrow frame edge.

Specifically in the display panel according to the embodiment of the invention, the display panel further includes a first clock signal line ck, a second clock signal line ckb, a first power supply line v1, and a second power supply line v2.

The first clock signal terminals CK of all the odd stages of shift register elements, and the second clock signal terminals CKB of all the even stages of shift register elements are connected with the first clock signal line ck.

The second clock signal terminals CKB of all the odd stages of shift register elements, and the first clock signal terminals CK of all the even stages of shift register elements are connected with the second clock signal line ckb.

The first signal terminals V1 of all the shift register elements are connected with the first power supply line v1.

The second signal terminals V2 of all the shift register elements are connected with the second power supply v2.

Specifically in the display panel according to the embodiment of the invention, as illustrated in FIG. 8A, the input signal terminal IN of the first stage of shift register element VSR1 is configured to receive a frame trigger signal STV.

Specifically in the display panel according to the embodiment of the invention, as illustrated in FIG. 8B which is an input-output timing diagram corresponding to a display panel according to an embodiment of the invention, after the first stage of shift register element receives the frame trigger signal STV, there are pulse signals output sequentially from the output signal terminals of the respective stages of shift register elements, where FIG. 8B illustrates only the output signals OUT1 to OUT6 of the first stage of shift register element to the sixth stage of shift register element by way of an example in which an active pulse signal is a low-level signal.

In the display panel according to the embodiment of the invention, the shift register elements can output stably using only two clock signal lines, so that less wiring may be deployed in the display panel, thus facilitating a design with a narrow frame edge.

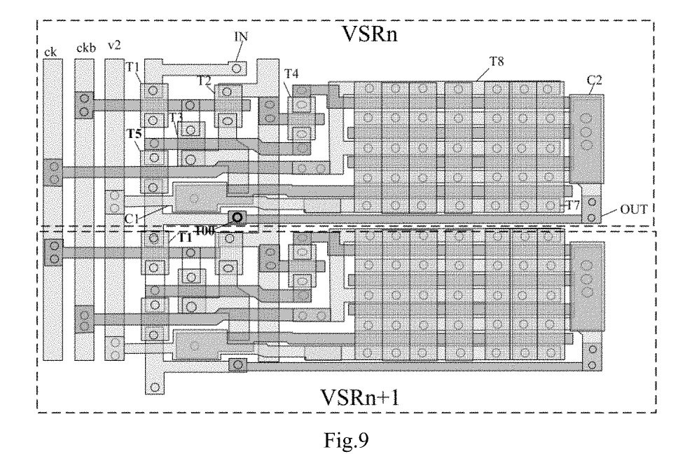

Specifically in the display panel according to the embodiment of the invention, as illustrated in FIG. 9 which is a schematic structural diagram of two adjacent stages of shift register elements in a display panel according to an embodiment of the invention, when the input module includes the first transistor, and the feedback and adjustment module includes only the fifth transistor, then the fifth transistor T5 of the n-th stage of shift register element VSRn, and the first transistor T1 of the (n+1)-th stage of shift register element VSRn+1 may be connected with the output signal terminal OUT of the n-th stage of shift register element VSRn through the same via-hole 100, where n is an integer more than 0 and less than N. Since the shift register element feeds back and adjusts the potential of the third node N using the signal of the output signal terminal OUT instead of the shift register element in the prior art adjusting the potential of the third node N through the first signal terminal or the second signal terminal, the invention has the fifth transistor T5 of the n-th stage of shift register element VSRn, and the first transistor T1 of the (n+1)-th stage of shift register element VSRn+1 connected with the output signal terminal OUT of the n-th stage of shift register element VSRn through the same via-hole 100, to thereby dispense with one via-hole, and the wiring for their connection so as to simplify the process thereof.

Specifically in order to enable the fifth transistor T5 of the n-th stage of shift register element VSRn, and the first transistor T1 of the (n+1)-th stage of shift register element VSRn+1 to share the same via-hole, in the display panel according to the embodiment of the invention, as illustrated in FIG. 9, the fifth transistor T5 of the n-th stage of shift register element VSRn, and the first transistor T1 of the (n+1)-th stage of shift register element VSRn+1 are arranged adjacent to each other.

Specifically in the display panel according to the embodiment of the invention, as illustrated in FIG. 9, the first pole of the fifth transistor T5 of the n-th stage of shift register element VSRn, and the first pole of the first transistor T1 of the (n+1)-th stage of shift register element VSRn+1 are connected with each other, so that the fifth transistor T5 and the first transistor T1 can be avoided from being further connected by bridging, etc, thus simplifying the process thereof, and also the width of the gap between two adjacent shift register elements can be reduced.

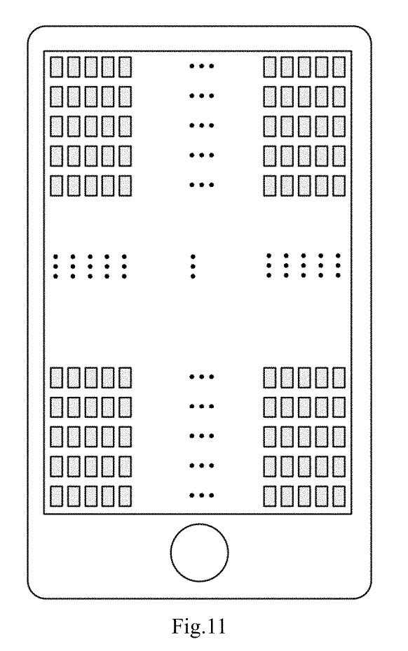

Based upon the same inventive idea, an embodiment of the invention further provides a display device as illustrated in FIG. 11 which is a schematic structural diagram of a display device according to an embodiment of the invention, where the display device includes the display panel according to any one of the embodiments above according to the invention. The display device can be a mobile phone, a tablet computer, a TV set, a display, a notebook computer, a digital photo frame, a navigator, and any other product or component capable of displaying. Reference can be made to the embodiments of the display panel above for an implementation of the display device, so a repeated description thereof will be omitted here.

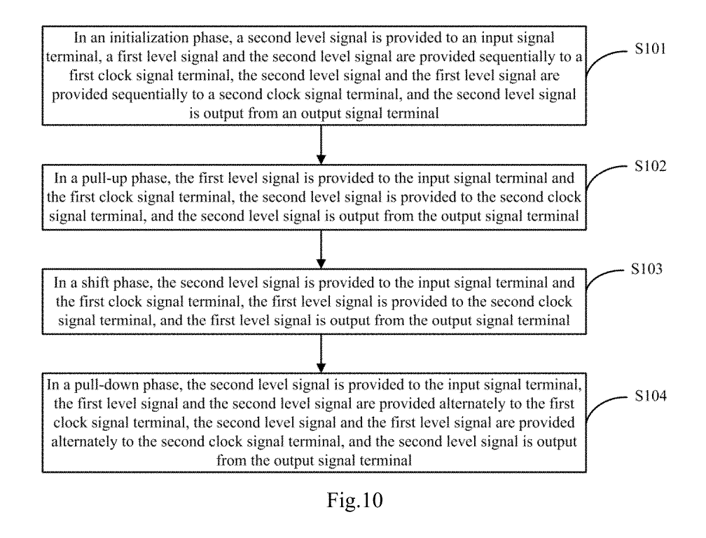

Based upon the same inventive idea, an embodiment of the invention further provides a method for driving the shift register element as described above. As illustrated in FIG. 10 which is a schematic flow chart of a driving method according to an embodiment of the invention, the method includes the following steps:

In the step S101, in an initialization phase, a second level signal is provided to an input signal terminal, a first level signal and the second level signal are provided sequentially to a first clock signal terminal, the second level signal and the first level signal are provided sequentially to a second clock signal terminal, and the second level signal is output from an output signal terminal.

In the step S102, in a pull-up phase, the first level signal is provided to the input signal terminal and the first clock signal terminal, the second level signal is provided to the second clock signal terminal, and the second level signal is output from the output signal terminal.

In the step S103, in a shift phase, the second level signal is provided to the input signal terminal and the first clock signal terminal, the first level signal is provided to the second clock signal terminal, and the first level signal is output from the output signal terminal.

In the step S104, in a pull-down phase, the second level signal is provided to the input signal terminal, the first level signal and the second level signal are provided alternately to the first clock signal terminal, the second level signal and the first level signal are provided alternately to the second clock signal terminal, and the second level signal is output from the output signal terminal.

Specifically in the driving method as illustrated in FIG. 10 according to the embodiment of the invention, when the first level signal is a low-level signal, and the second level signal is a high-level signal, the timing diagram is illustrated in FIG. 7A, where reference can be made to the T1 phase and the T2 phase in the first and second embodiments above for an exemplary operating principle of the initialization phase, reference can be made to the T3 phase in the first and second embodiments above for an exemplary operating principle of the pull-up phase, reference can be made to the T4 phase in the first and second embodiments above for an exemplary operating principle of the shift phase, and reference can be made to the T5 phase in the first and second embodiments above for an exemplary operating principle of the pull-down phase, so a repeated description thereof will be omitted here.

Specifically in the driving method as illustrated in FIG. 10 according to the embodiment of the invention, when the first level signal is a high-level signal, and the second level signal is a low-level signal, the timing diagram is illustrated in FIG. 7B, where reference can be made to the T1 phase and the T2 phase in the first and second embodiments above for an exemplary operating principle of the initialization phase, reference can be made to the T3 phase in the first and second embodiments above for an exemplary operating principle of the pull-up phase, reference can be made to the T4 phase in the first and second embodiments above for an exemplary operating principle of the shift phase, and reference can be made to the T5 phase in the first and second embodiments above for an exemplary operating principle of the pull-down phase, so a repeated description thereof will be omitted here.

In the shift register element, the method for driving the same, and the display panel according to the embodiments of the invention, the shift register element includes the input module, the first control module, the second control module, the feedback and adjustment module, the output module, the first coupling module, and the second coupling module; the feedback and adjustment module feeds the signal of the output signal terminal back to the first node under the control of the second clock signal terminal, and the second control module connects the first node with the third node under the control of the first signal so as to shorten a period of time for which the third node is floating; and the first control module provides the second node with the signal of the first clock signal terminal or the first signal terminal under the control of the first clock signal terminal so as to shorten a period of time for which the second node is floating. Since there are the shorter periods of time for which the second node and the third node are floating respectively, and the circuit is free of the problem of node potential contention, the shift register element can be highly robust against interference, output more stably, and have a larger process window. Moreover since there are two clock signal terminals in the shift register element, there will be a smaller number of clock signals as needed, so that less wiring may be deployed, thus facilitating a design with a narrow frame edge.

Evidently those skilled in the art can make various modifications and variations to the invention without departing from the spirit and scope of the invention. Accordingly the invention is also intended to encompass these modifications and variations thereto so long as the modifications and variations come into the scope of the claims appended to the invention and their equivalents.

What is claimed is:

1. A shift register element, comprising an input module, a first control module, a second control module, a feedback and adjustment module, an output module, a first coupling module, and a second coupling module;
wherein the input module is connected with an input signal terminal and a first clock signal terminal, and configured to transmit a signal of the input signal terminal to a first node under the control of the first clock signal terminal;
wherein the first control module is connected with the first clock signal terminal, and configured to transmit a signal of the first clock signal terminal to a second node under the control of the first clock signal terminal, or the first control module is connected respectively with a first signal terminal and the first clock signal terminal, and configured to transmit a signal of the first signal terminal to the second node under the control of the first clock signal terminal;
wherein the second control module is connected with the first clock signal terminal and the first signal terminal, and configured to transmit the signal of the first clock signal terminal to the second node under the control of the first node, and to connect the first node with a third node under the control of the first signal terminal;
wherein the feedback and adjustment module is connected respectively with a second clock signal terminal and an output signal terminal, and configured to transmit a signal of the output signal terminal to the first node under the control of the second clock signal terminal;
wherein the output module is connected respectively with the second clock signal terminal and a second signal terminal, and configured to transmit a signal of the second signal terminal to the output signal terminal under the control of the second node, and to transmit a signal of the second clock signal terminal to the output signal terminal under the control of the third node;
wherein the first coupling module comprises a first capacitor connected between the third node and the output signal terminal, and configured to couple the output signal terminal with a potential of the third node; and
wherein the second coupling module comprises a second capacitor connected between the second node and the second signal terminal, and configured to stabilize a potential of the second node.

2. The shift register element according to claim 1, wherein the input module comprises a first transistor, wherein the first transistor has a gate connected with the first clock signal terminal, wherein a first pole connected with the input signal terminal, and a second pole connected with the first node.

3. The shift register element according to claim 1, wherein the first control module comprises a second transistor,
wherein the second transistor has a gate connected with the first clock signal terminal, wherein a first pole connected with the first signal terminal or the first clock signal terminal, and a second pole connected with the second node.

4. The shift register element according to claim 1, wherein the second control module comprises a third transistor and a fourth transistor;
wherein the third transistor has a gate connected with the first node, a first pole connected with the first clock signal terminal, and a second pole connected with the second node; and
wherein the fourth transistor has a gate connected with the first signal terminal, a first pole connected with the first node, and a second pole connected with the third node.

5. The shift register element according to claim 1, wherein the feedback and adjustment module comprises a fifth transistor; and
the fifth transistor has a gate connected with the second clock signal terminal, a first pole connected with the output signal terminal, and a second pole connected with the first node.

6. The shift register element according to claim 5, wherein the feedback and adjustment module further comprises a sixth transistor connected between the first pole of the fifth transistor, and the output signal terminal,
wherein the sixth transistor has a gate connected with the second node, a first pole connected with the output signal terminal, and a second pole connected with the first pole of the fifth transistor.

7. The shift register element according to claim 1, wherein the output module further comprises a seventh transistor and an eighth transistor,
wherein the seventh transistor has a gate connected with the second node, a first pole connected with the second signal terminal, and a second pole connected with the output signal terminal; and
wherein the eighth transistor has a gate connected with the third node, a first pole connected with the second clock signal terminal, and a second pole connected with the output signal terminal.

8. The shift register element according to claim 2, wherein all the transistors are either P-type transistors, or N-type transistors.

9. A display panel, comprising N cascaded shift register elements according to claim 1, wherein:
the output signal terminal of each stage of the shift register elements other than the last stage is connected with the input signal terminal of a next stage of said shift register element.

10. The display panel according to claim 9, wherein when the input module of each stage of shift register element comprises a first transistor, and the feedback and adjustment module of each stage of shift register element comprises a fifth transistor, then the fifth transistor of the n-th stage of shift register element and the first transistor of the (n+1)-th stage of shift register element are connected with the output signal terminal of the n-th stage of shift register element through a common via-hole, wherein n is an integer more than 0 and less than N.

11. The display panel according to claim 10, wherein the fifth transistor of the n-th stage of shift register element, and the first transistor of the (n+1)-th stage of shift register element are arranged adjacent to each other.

12. The display panel according to claim 11, wherein the first pole of the fifth transistor of the n-th stage of shift register element, and the first pole of the first transistor of the (n+1)-th stage of shift register element are connected with each other.

13. The display panel according to claim 9, wherein the display panel further comprises a first clock signal line, a second clock signal line, a first power supply line, and a second power supply line;
wherein the first clock signal terminals of all the odd stages of shift register elements, and the second clock signal terminals of all the even stages of shift register elements are connected with the first clock signal line;
wherein the second clock signal terminals of all the odd stages of shift register elements, and the first clock signal terminals of all the even stages of shift register elements are connected with the second clock signal line;
wherein the first signal terminals of all the shift register elements are connected with the first power supply line; and
wherein the second signal terminals of all the shift register elements are connected with the second power supply line.

14. A method for driving the shift register element according to claim 1, the method comprising:
in an initialization phase, providing the input signal terminal with a second level signal, providing the first clock signal terminal with a first level signal and the second level signal sequentially, providing the second clock signal terminal with the second level signal and the first level signal sequentially, and outputting the second level signal from the output signal terminal;
in a pull-up phase, providing the input signal terminal and the first clock signal terminal with the first level signal, providing the second clock signal terminal with the second level signal, and outputting the second level signal from the output signal terminal;
in a shift phase, providing the input signal terminal and the first clock signal terminal with the second level signal, providing the second clock signal terminal with the first level signal, and outputting the first level signal from the output signal terminal; and
in a pull-down phase, providing the input signal terminal with the second level signal, providing the first clock signal terminal with the first level signal and the second level signal alternately, providing the second clock signal terminal with the second level signal and the first level signal alternately, and outputting the second level signal from the output signal terminal.
